(19) United States
(12) Patent Application Publication
(10) Pub. No.: US 2025/0126849 A1
(43) Pub. Date: Apr. 17, 2025

(54) NON-VOLATILE MEMERY CELL AND METHOD OF FORMING THE SAME

(71) Applicant: TAIWAN SEMICONDUCTOR MANUFACTURING COMPANY, LTD., Hsinchu (TW)

(72) Inventor: Wen-Chao SHEN, Hsinchu (TW)

(21) Appl. No.: 18/487,063

(22) Filed: Oct. 14, 2023

(51) Int. Cl. H01L 29/792; G11C 16/04; G11C 16/10; G11C 16/14; H01L 29/66; H01L 29/78; H10B 43/35

(52) U.S. Cl. CPC H10D 30/69; G11C 16/0466; G11C 16/10; G11C 16/14; H10B 43/35; H10D 30/024; H10D 30/0413; H10D 30/6211; G11C 2216/02

(57) ABSTRACT

Embodiments the present disclosure provide a MTP memory cell and methods for forming the same. The MTP memory cell includes a FinFET transistor having a storage node formed around the channel region and a metal gate electrode around the storage node. The memory cell may be implemented by either n-channel transistor or p-channel transistor.

### BACKGROUND

Many modern electronic devices contain electronic memory configured to store data. Electronic memory may be volatile memory or non-volatile memory (NVM). Volatile memory stores data while it is powered, while NVM is able to keep data when power is removed. Multi-time programmable (MTP) cells are one promising candidate for next generation NVM. NVMs are sometimes embedded in integrated circuits and are referred to as eNVM. Conventional eNVM use floating polycrystalline gate as charge storage node. While thin oxide and metal gate process during technology shrinking become the bottleneck of eNVM. Embodiments of the present disclosure provide a novel NVM cell suitable as eNVM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

Figurers 1A-1C illustrate various views of a memory cell according to the present disclosure.

FIG. 2A illustrates a block diagram of a circuit according to one embodiment of the memory cell of FIGS. 1A-1C.

FIGS. 2B and 2C illustrate operation status of the memory cell of FIG. 2A.

FIG. 2D illustrates a block diagram of a circuit according to another embodiment of the memory cell of FIGS. 1A-1C.

FIGS. 2E and 2F illustrate operation status of the memory cell of FIG. 2D.

FIGS. 3A-3B illustrates a table corresponding to operation conditions of the memory cell of FIGS. 1A-1C.

FIGS. 4A-4B illustrate various views of a memory cell according to the present disclosure.

FIG. 5A is a layout view of a memory circuit according to embodiments of the present disclosure.

FIGS. 5B-5C are schematic sectional views of a memory cell in the memory circuit of FIG. 5A.

FIG. 5D is a block diagram of the memory circuit of FIG. 5A.

FIG. 6A is a layout view of a memory circuit according to embodiments of the present disclosure.

FIG. 6B is a schematic circuit of the memory circuit of FIG. 6A.

FIG. 7 is a flow chart of a method for forming a memory cell according to embodiments of the present disclosure.

FIGS. 8-10, 10A-10C, 11, 11A-11C, 12, 12A-12C, and 13A-13C illustrates various views of the forming a memory cell according to embodiment of the present disclosure.

FIG. 14 is a flow chart of a method for forming a memory cell according to embodiments of the present disclosure.

FIGS. 15, 15A-15C, 16, 16A-16C, and 17A-17C illustrates various views of the forming a memory cell according to embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the provide a MTP memory cell includes a Fin field effect transistor (FinFET) having a storage gate and a control gate. The storage gate comprises a silicon nitride gate electrode. The control gate includes a metal containing gate electrode. The storage gate surrounds a channel region of the FinFET. The control gate embraces the storage gate. In some embodiments, the storage gate and the control gate may be formed using a cut metal gate sequence in a process for fabricating complementary metal-oxide semiconductor (CMOS) transistors. The MTP memory cell according to the present disclosure may be formed from P-type FinFET or N-type FinFET.

The configuration of storage gate and metal control gate enables high-efficiency of programming and erase. Electrons may be selectively trapped in the storage gate of the MTP cell so that the MTP cell may be selectively set in a programmed state or an erased state. For example, in the programmed stated, electrons are trapped in the storage gate leading to a low read current. In the erased state, electrons are emptied out from the storage gate leading to a high read current. The MTP cell may be programmed or erased by applying a suitable control voltage to the control gate. The MTP cell may be programmed and/or erased by Fowler-Nordheim (FN) tunneling, CHE (channel hot electron injection), or BBHH (band-to-band hot hole injection).

FIGS. 1A-1C illustrate various views of a memory cell 100 according to the present disclosure. FIG. 1C is a schematic top view of the memory cell 100. FIG. 1A is a schematic cross sectional view of the memory cell 100 along the A-A line in FIG. 1C. FIG. 8 is a schematic cross sectional view of the memory cell 100 along the B-B line in FIG. 1C. As shown in FIGS. 1A-1C, the memory cell 100 is a FinFET transistor formed on a semiconductor substrate 102. The memory cell 100 may include a fin shaped channel region 104. The fin shaped channel region 104 may be formed from the semiconductor substrate 102 and surrounded by an isolation region 106. The memory cell 100 includes a gate structure 110 extending along a direction substantially perpendicular to the fin shaped channel region 104. The gate structure 110 is formed over the fin shaped channel region 104 and the isolation region 106. A source region 108s and a drain region 108d are disposed on opposite sides of the gate structure 110. The source region 108s and the drain region 108d may be epitaxially grown from the fin shaped channel region 104.

The gate structure 110 may include a first gate dielectric layer 114, a second gate dielectric layer 118, a third gate dielectric layer 120, a first gate electrode layer 112 and a second gate electrode layer 116 disposed between two sidewall spacers 122. The sidewall spacers 122 separates the source region 108s and the drain region 108d from the gate dielectric layers 114, 118, 120 and the gate electrode layers 112, 116. The first gate dielectric layer 114 is disposed over the fin shaped channel region 104 and portions of the sidewall spacers 122. The first gate electrode layer 112 is disposed over the first gate dielectric layer 114 and surrounds the fin shaped channel region 104 between the sidewall spacers 122. In some embodiments, the first gate electrode layer 112 may be disposed substantially symmetrically about a central line 101 of the fin shaped channel region 104. A shown in FIG. 1A, the first gate electrode layer 112 are disposed on sidewalls 104s of the fin shaped channel region 104. In some embodiments, the first gate electrode layer 112 may extend to a distance D from both sides of the fin shaped channel region 104. The second gate electrode layer 116 is disposed outside the first gate electrode layer 112. In some embodiments, two portions of the second gate electrode layer 116a, 116b are disposed on both sides of the first gate electrode layer 112. The second gate electric layer 118 is disposed between the first gate electrode layer 112 and the second gate electrode layer 116. The third gate dielectric layer 120 is disposed between the second gate electrode layer 116 and the sidewall spacers 122 and between the second gate electrode layer 116 and the isolation region 106.

The first gate electrode layer 112 and the first gate dielectric layer 114 form a storage node 130 for the memory cell 100. Charge carriers, such as electrons, may be stored in or erased from the storage node 130. The second electrode layer 116 adjacent the storage node 130 may be used as a control gate to program and erase the storage node 130. By connecting the second electrode layer 116 through interconnect lines, appropriate control gate voltage may be applied to the storage node 130 to program and erase the memory cell 100. Efficiency of program and eras operations can be improved by selecting appropriate control gate voltages. Moreover, the distance D between the second gate electrode 116 and the channel region 104 may be selected to obtain desired cell coupling ratio. For example, decreasing the distance D may improve efficiency of program/erase operations. In some embodiments, the distance D is in a range between about 5 nm and about 100 nm. A distance D greater than 100 nm may not achieve effective program erase operation. A distance D less than 5 nm may not provide storage volume in the storage node 130 to trap sufficient electrons to induce a detectable difference between the programed state and the erased state.

Different combination of voltage may be applied to the second gate electrode layer 116, the source region 108s, and the drain region 108d to program (charge), erase, and read the charges in the storage node 130. Gate contact features 124a, 124b are formed in contact with the second gate electrode layers 116a, 116b. In some embodiments, the gate contact features 124a, 124b are electrically connected by a control line 126. Control voltages may be applied to the second gate electrode layer 116a, 116b via the control line 126. A source contact feature 128s and a drain contact feature 128d are in contact with the source region 108s and the drain region 108d respectively. Voltages may be applied to the source region 108s and the drain region 108d via the source contact feature 128s and drain contact feature 128d respectively.

The semiconductor substrate 102 may be or comprise a bulk semiconductor substrate (e.g., a bulk silicon substrate), a silicon-on-insulator (SOI) substrate, or another suitable substrate material. In some embodiments, the semiconductor substrate 102 may include one or more doped region.

The fin shaped channel region 104 may be formed in a discrete doped region or a well region in the semiconductor substrate 102. The fin shaped channel region 104 may include p-type dopants or n-type dopants resulting in the memory cell 100 being a p-type FinFET or a n-type FinFET.

The source region 108s and the drain region 108d may include one or more layers of Si, SiP, SiC and SiCP for n-type device or Si, SiGe, Ge for p-type devices. For n-type devices, the source region 108s and the drain region 108d also include n-type dopants, such as phosphorus (P), arsenic (As), etc. For p-type devices, the source region 108s and the drain region 108d may include p-type dopants, such as boron (B).

The first gate electrode layer 112 may be formed from silicon nitride, silicon oxynitride, alloy of silicon oxide and silicon nitride, a combination thereof, or any suitable material for storing charges therein.

The first gate electrode layer 116 may be one or more layer of electrical conductive material, such as, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the first gate electrode layer 116 may include tungsten, aluminum, titanium nitride, tantalum nitride, or a combination thereof.

The first, second, and third gate dielectric layer 114, 118, 120 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the first, second, and third gate dielectric layer 114, 118, 120 may include SiOx, HfOx, and ZrOx, or a combination thereof. The first, second, and third gate dielectric layer 114, 118, 120 may have the same or different composition and/or thickness according to the circuit design.

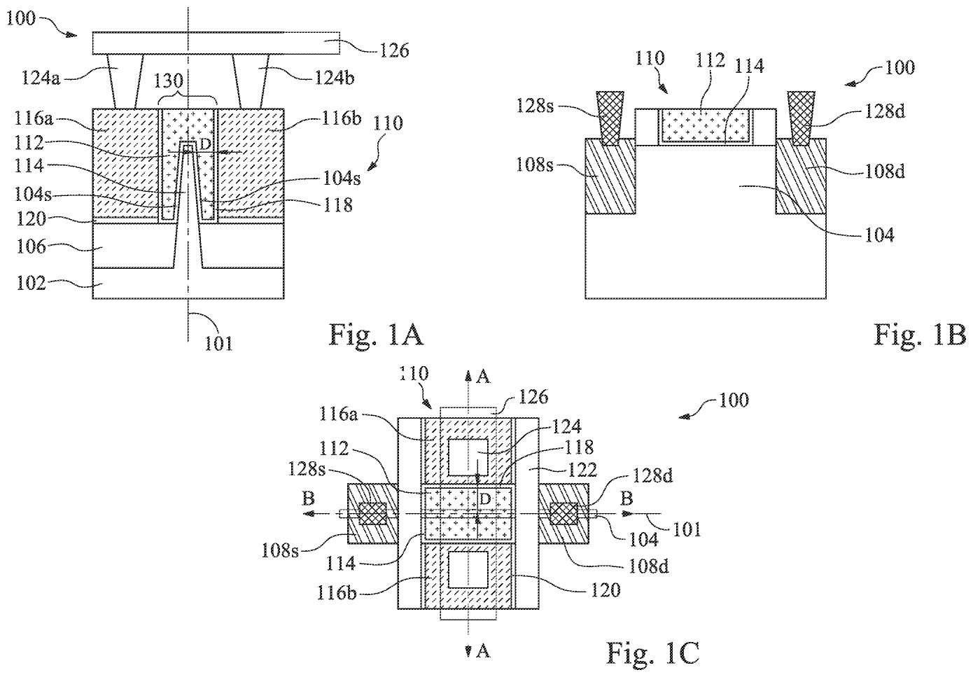

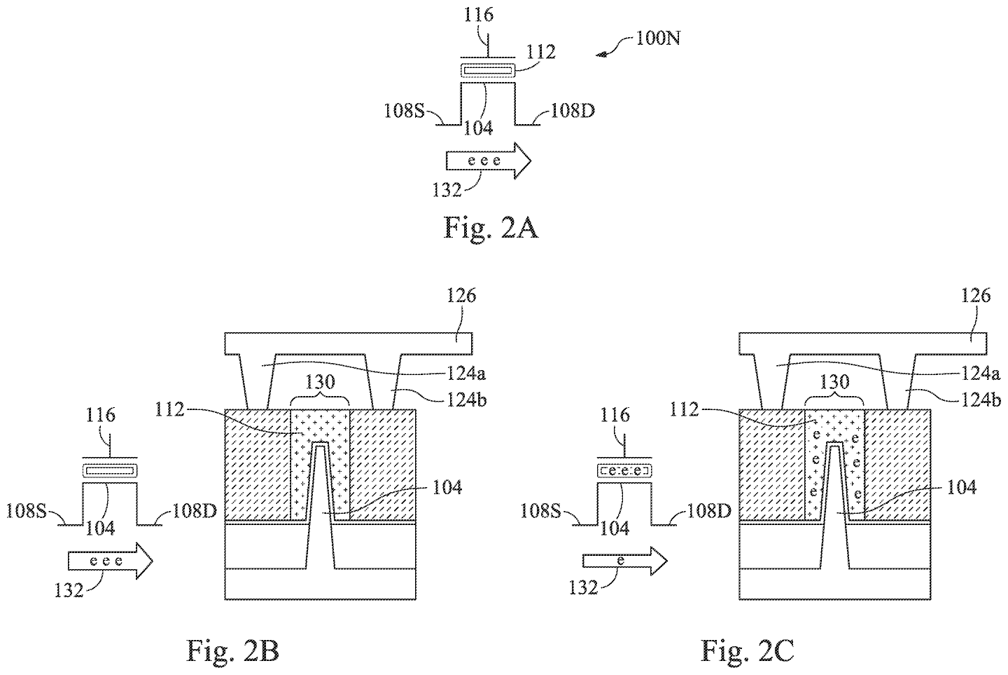

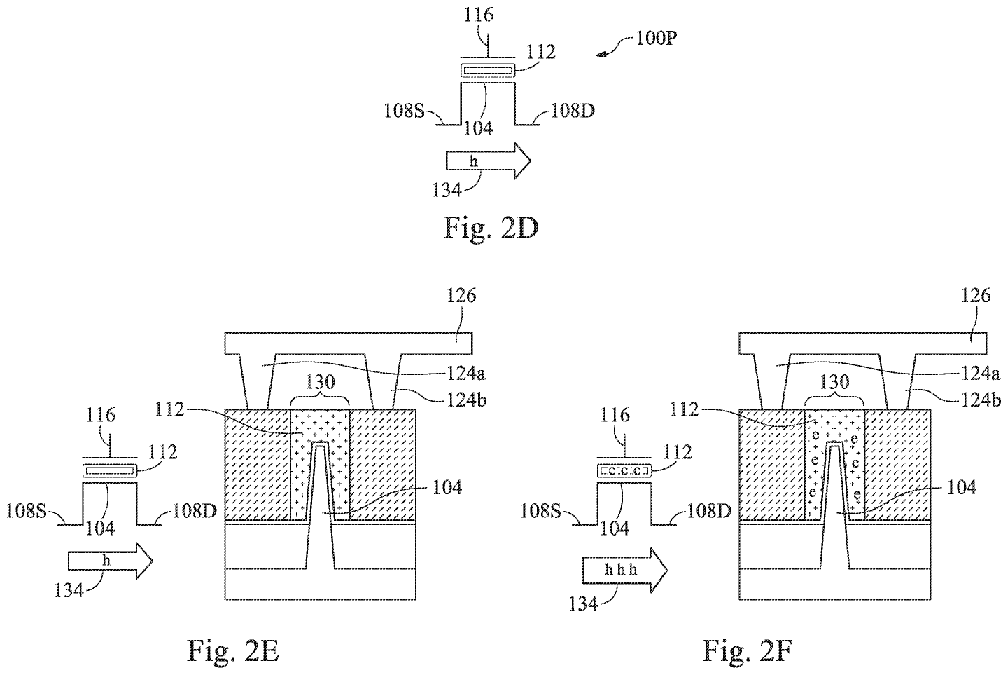

FIG. 2A illustrates a block diagram of a circuit of the memory cell 100 of FIGS. 1A-1C. FIGS. 2B and 2C illustrate operation status of the memory cell 100 of FIGS. 1A-1C. As shown in FIG. 2A, the source region 108s, the drain region 108d, the channel region 104, and the gate structure 110 form a n-type field effect transistor 100N, in which majority of current carriers are electrons. In this case, the transistor 100N is a N-type FinFET. In some embodiments, the transistor 100N is a N-channel enhancement-type MOSFET. When the transistor 100N is turned ON, i.e., a sufficient positive voltage Vdd is applied to the drain region 108d and a sufficient positive voltage, e.g. Vdd, is applied to the second gate electrode 116, a current 132 of electrons flows through the channel region 104. In some embodiments, the voltage Vdd indicates the positive power supply voltage of the MOSFET circuit. The voltage Vdd may be about 5V, about 3.3V, about 1.8V, about 1.2V, or any suitable value according to circuit design.

FIG. 2B shows the transistor 100N of the memory cell 100 in an initial state or an erased state, in which electrons are not trapped or pushed out from in the first gate electrode layer 112 of the storage node 130. When the transistor 100N is turned ON under the initial or erased state, a normal or high current 132 of electrons flows through the channel region 104.

FIG. 2C shows the transistor 100N of the memory cell 100 in a programmed state, in which a portion of carrier electrons in the channel region 104 are trapped in the first gate electrode layer 112 of the storage node 130. When the transistor 100N is turned ON under the programmed state, reduced carrier electrons in the channel region 104 lowers the current 132, resulting in a low current state.

During a read operation, the transistor 100N is turned ON and value of the memory cell 100 is obtained by the current 132. A high current 132 through the channel region 104 indicates that the memory cell 100 is in an erased or initial state while a low current 132 through the channel region 104 indicates that the memory cell 100 is in programmed state.

Alternatively, the source region 108s, the drain region 108d, the channel region 104, and the gate structure 110 may also a P-type transistor and function as a in the similar manner.

FIG. 2D illustrates a block diagram of a circuit according to another embodiment of the memory cell 100. In FIG. 2D, the source region 108s, the drain region 108d, the channel region 104, and the gate structure 110 form a P-type field effect transistor 100P, in which majority of current carriers are holes. In this case, the transistor 100P is a P-type FinFET. In some embodiments, the transistor 100P is a P-channel enhancement-type MOSFET. When the transistor 100P is turned ON, i.e., a sufficient negative voltage −Vdd is applied to the drain region 108d, 0V is applied to source region 108s, and a negative voltage −Vdd is applied to the second gate electrode 116.

FIGS. 2E and 2F illustrate operation status of the memory cell of FIG. 2D. FIG. 2E shows the transistor 100P of the memory cell 100 in an initial state or an erased state, in which electrons are not trapped or pushed out from in the first gate electrode layer 112 of the storage node 130. When the transistor 100P is turned ON under the initial or erased state, a normal or low current 134 of holes flows through the channel region 104.

FIG. 2F shows the transistor 100P of the memory cell 100 in a programmed state, in which electrons in the channel region 104 are trapped in the first gate electrode layer 112 of the storage node 130 creating extra carrier holes in the channel region 104. When the transistor 100N is turned ON under the programmed state, the extra carrier holes in the channel region 104 enables a high current 134, resulting in a high current state.

During a read operation, the transistor 100P is turned ON and value of the memory cell 100 is obtained by the current 134. A low current 134 through the channel region 104 indicates that the memory cell 100 is in an erased or initial state while a high current 134 through the channel region 104 indicates that the memory cell 100 is in programmed state.

As discussed above, the memory cell 100 is a multi-time programmable MTP cell with two states: a programed state and an erased state. Electrons are stored in the storage node 130 in programmed state and released from the storage node 130 in the erased state. The electrons stored in the storage node 130 affects the threshold voltage of the memory cell 100 and the current through the channel region 104. For the memory cell with a n-channel, the programed state has a low current and the erased state has a high current. For the memory cell with a p-channel, the programed state has a high current and the erased state has a low current.

By applying proper voltages on the source region 108s, the drain region 108d, and the second gate electrode 116 or the control gate, the memory cell 100 can be programed and erased. The memory cell 100 may be programmed by Fowler-Nordheim (FN) tunneling or by channel hot electron injection (CHE). The memory cell 100 may be erased by Fowler-Nordheim (FN) tunneling or by band-to-band hot hole injection (BBHH).

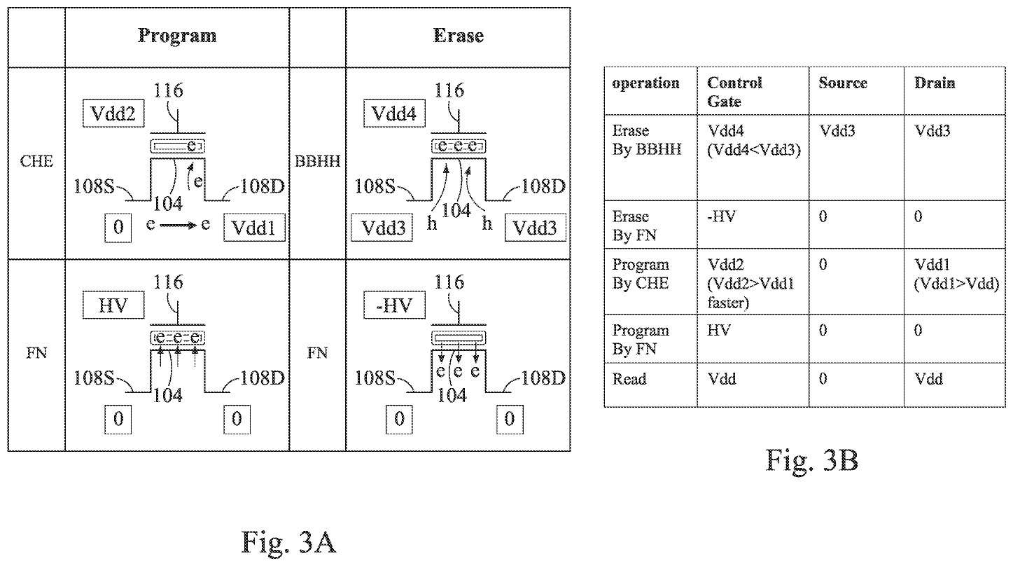

FIG. 3A illustrates a table corresponding to program and erase operation conditions of the memory cell 100. Particularly, FIG. 3A illustrates program and erase operations for the memory cell 100 with a N-type FET 100N.

To program the memory cell with a N-type FET 100N using channel hot electron injection (CHE), a positive voltage Vdd2 is applied to the control gate or the second gate electrode 116, a positive voltage Vdd1 is applied to the drain region 108d while the voltage applied on the source region 108s is about 0V. The FET 100N is turned on by the positive voltages Vdd2 and Vdd1, resulting in a current of electrons through the channel region 104. A portion of the electrons in the current may be injected into and trapped in the storage node 130, turning the memory cell 100 to the programmed state. In some embodiments, the positive voltages Vdd1 and Vdd2 are greater than Vdd. The voltages Vdd1 and Vdd2 may be selected according to circuit design. In some embodiments, the voltage Vdd2 is greater than the voltage Vdd1 to obtain increased charging speed.

To program the memory cell with a N-type FET 100N using Fowler-Nordheim (FN) tunneling, a positive high voltage HV is applied to the control gate or the second gate electrode 116 while voltages applied on the source region 108s and the drain region 108d are about 0V. When the positive high voltage HV is applied to the second gate electrode 116, electrons in the channel region 104 are “sucked” into and trapped in the storage node 130, turning the memory cell 100 to the programmed state. In some embodiments, the high voltage HV may, for example, be within a range of about 7 to 10 V, within a range of about 11 to 18 V, within a range of about 7 to 18 V, or another suitable value.

To erase the memory cell with a N-type FET 100N using band-to-band hot hole injection (BBHH), a negative voltage Vdd4 is applied to the control gate or the second gate electrode 116 to attract hole injecting into the storage gate, a positive voltage Vdd3 is applied to the drain region 108d and to the source region 108s. The positive voltage Vdd4 is lower than the positive voltage Vdd3. The higher voltage Vdd3 in the source region 108s and the drain region 108d drives hot holes in the channel region 104 into the storage node 130 to erase the trapped electrons in the storage node 130, thereby, turning the memory cell to the erased state. In some embodiments, the positive voltages Vdd3 and Vdd4 are greater than Vdd.

To erase the memory cell with a N-type FET 100N using Fowler-Nordheim (FN) tunneling, a negative high voltage −HV is applied to the control gate or the second gate electrode 116 while voltages applied on the source region 108s and the drain region 108d are about 0V. When the negative high voltage −HV is applied to the second gate electrode 116, electrons trapped in the storage node 130 are driven back into the channel region 104, turning the memory cell 100 to the erased state. In some embodiments, the high voltage HV may, for example, be within a range of about 7 to 10 V, within a range of about 11 to 18 V, within a range of about 7 to 18 V, or another suitable value.

The program and erase methods may be mixed and combined according to circuit design. FIG. 3B is a table showing voltage conditions applied to the control gate or the second gate electrode 116, the source region 108s, and the drain regions for various operations.

Even though one fin shaped channel region 104 is shown in the memory cell 100. Memory cells according to the present disclose may include two or more fin structures to obtain greater channel region.

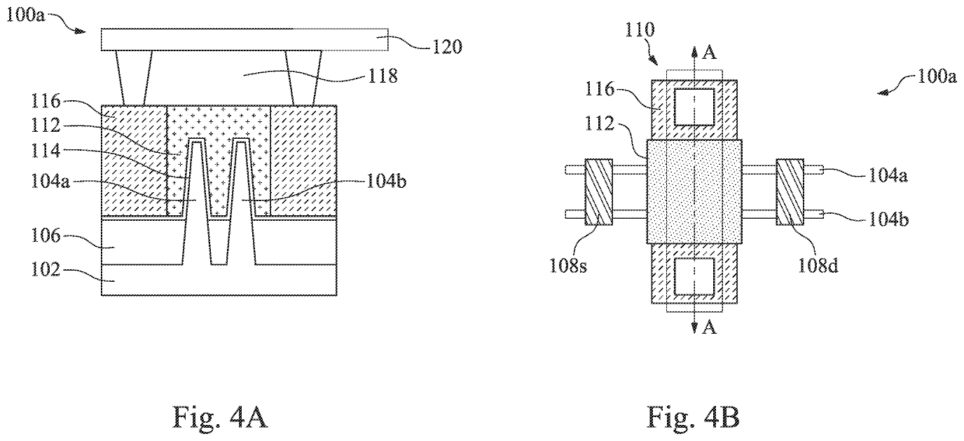

FIGS. 4A-4B illustrate various views of a memory cell 100a according to the present disclosure. FIG. 4B is a schematic top view of the memory cell 100a. FIG. 4A is a schematic cross sectional view of the memory cell 100a along the A-A line in FIG. 4B. The memory cell 100a is substantially similar to the memory cell 100 except that the memory cell 100a includes two fin shaped channel regions 104 forming an increased channel region.

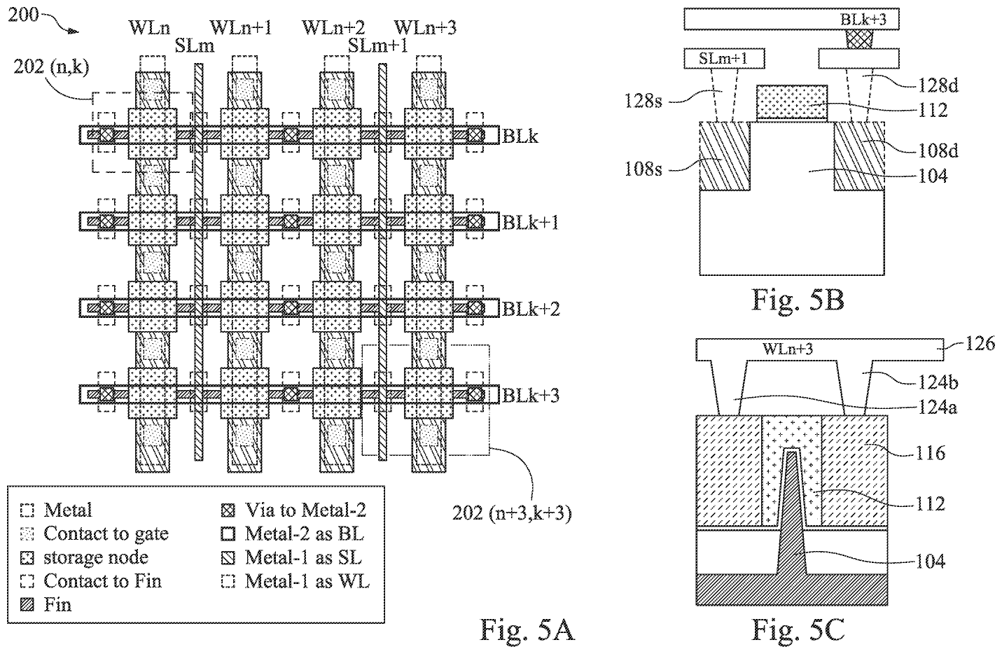

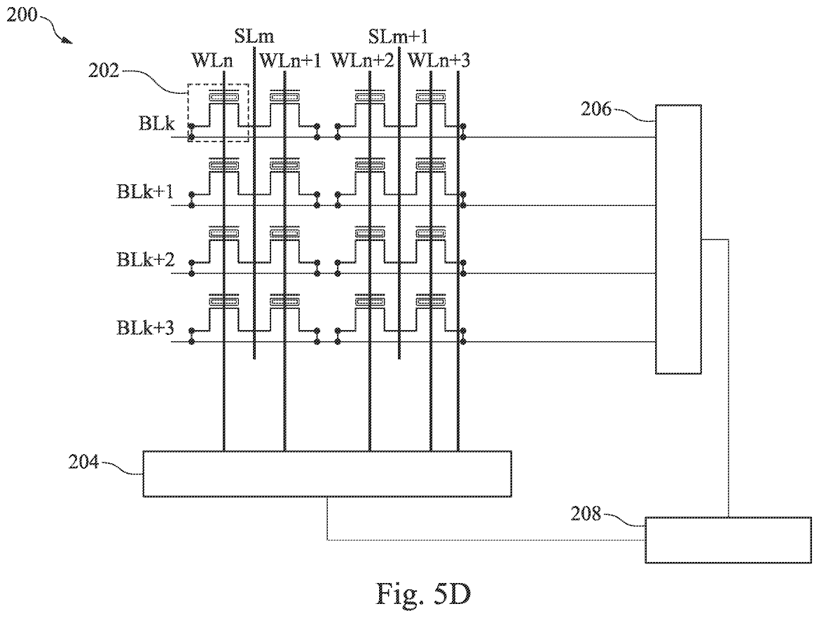

FIG. 5A is a layout view of a memory circuit 200 according to embodiments of the present disclosure. FIGS. 5B-5C are schematic sectional views of a memory cell 100 in the memory circuit 200 of FIG. 5A. FIG. 5D is a schematic circuit of the memory circuit 200 of FIG. 5A.

The memory circuit 200 comprises a plurality of rows and columns of memory cells 202. In some embodiments, each memory cells 202 may have a structure similar to the memory cell 100 or the memory cell 100a. The memory circuit 200 includes a plurality of memory cells 202, a plurality of bit lines BLk (k is an integer), a plurality of source lines SLm (m is an integer), a plurality of word lines WLn (n is an integer), a word line decoder 204, a bit line decoder 206, and a control circuit 208. The plurality of word lines WLn are electrically connected to the word line decoder 204. The plurality of bit lines BLk are electrically connected to the bit line decoder 206. The memory cells 202 in the k^{th} row and n^{th} column may be identified by 202 (n,k). In some embodiments, the plurality of source lines SLm are electrically coupled to support read circuitry (not shown) such as a multiplexer and/or an amplifier configured to determine an output of a read operation.

In FIGS. 5A and 5D, a portion of the memory circuit 200 with 16 memory cells 202 are shown. Particularly, four word lines WLn, WLn+1, WLn+2, WLn+3 are shown, four bit lines BLk, BLK+1, BLk+2, BLk+3 are shown, and two source lines SLm, SLm+1 are shown in FIGS. 5A and 5D.

In FIG. 5A, the memory cells 202 may be configured as the memory cell 100 of FIGS. 1A-1C. The memory cells 202 are arranged within a memory array comprising rows and columns. The memory cells 202 within a column of the memory array are operably coupled to a word line WLn while the memory cells 202 within a row of the memory array are operably coupled to a bit line BLk. Therefore, the plurality of memory cells 202 to be respectively associated with an address defined by an intersection of a word line WLn and a bit like BLk.

The memory array is electrically coupled to support circuitry that is configured to perform a write operation (i.e., an erase operation and/or a program operation) and/or a read operation on the plurality of memory cells 202. In some embodiments, the support circuitry includes the control circuit 208, the word line decoder 204, and the bit line decoder 206. In some embodiments, the control circuit 208 is a microprocessor circuit.

In some embodiments, the memory array in FIGS. 5A and 5D is an NOR-array. The control gate or the second gate electrode layer 116 of the memory cell 100 is connected to the corresponding word line WLk. The source region 108s of each memory cell 100 is connected to a corresponding source line SLm. The drain region 108d of each memory cell 100 is connected to a corresponding bit line BLk. The word line WLn, the bit line BLk, and the source line SLm function together to complete read, program, and erase operations.

In some embodiments, two neighboring memory cells 100 in the same row are mirror images of each other so that the source regions 108s can merge to connect with one source line SLm to increase cell density. Similarly, the drain regions 108d of neighboring memory cells 100 in the same row can merge to connect with one bit line connector to increase cell density.

FIGS. 5B and 5C are partial cross sectional views of one memory cell 202 (n+3, k+3) in the memory circuit 200 to show connection arrangement according to one embodiment of the present disclosure. The word lines WLn and the source lines SLm may be arranged along a first direction and in the same intermetal dielectric (IMD) layer, for example a first IMD layer. The bit lines BLk may be arranged along a second direction perpendicular to the first direction, and in a different IMD layer, for example in a second IMD layer.

The control circuit 208 is configured to control the word line decoder 204 and/or the bit line decoder 206 to complete read, program, and erase operations. For example, the control circuit 208 may supply an address (e.g., the address is associated with a single memory cell 202 in the memory array) to the word line decoder 204 and/or the bit line decoder 206. In some embodiments, the word line decoder 204 is configured to selectively apply a signal (e.g., a current and/or a voltage) to the word lines WLn based upon the received address. The bit line decoder 206 is configured to selectively apply a signal (e.g., a current and/or a voltage) to the bit lines BLk based upon the received address. The multiplexer and/or amplifier may determine an output of a read operation according to the current through corresponding source line SLm.

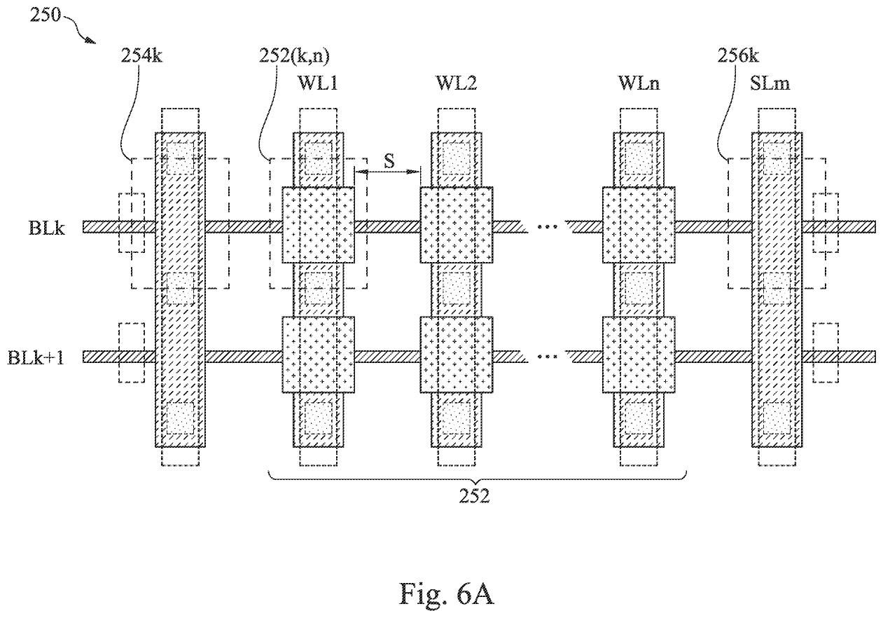

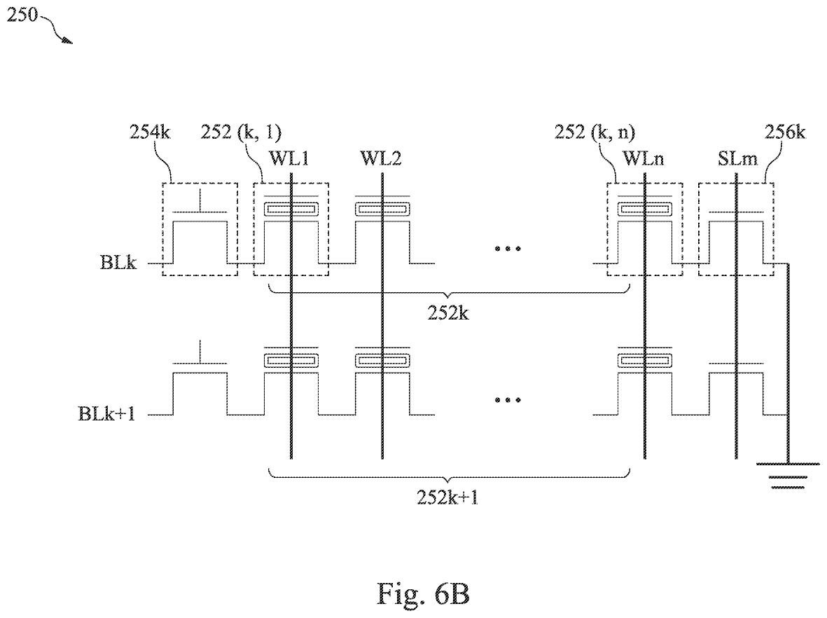

FIG. 6A is a layout view of a memory circuit 250 according to embodiments of the present disclosure. FIG. 6B is a schematic circuit of the memory circuit 250 of FIG. 6A. The memory circuit 250 may be placed and designed as NAND-type memory array. In some embodiments, the memory circuit 250 includes a plurality of multi-MTP cells 252. Each multi-MTP cell 252 includes a cell chain having n memory cells 252₁, . . . 252ₙ formed in a row. Each of the memory cells 252₁, . . . 252ₙ may be a FinFET transistor with a storage node and a control gate formed over the storage node. The memory cells 252₁, . . . 252ₙ may be fabricated from the same semiconductor fin or semiconductor fins. The number n may be 8, 16, or other suitable number according to the circuit design. In some embodiments, the memory cells 252₁, . . . 252ₙ may be similar to the memory cell 100, 100a described above.

Each multi-MTP cell 252 further includes a bit line select transistor 254 and a ground select transistor 256. The bit line select transistor 254 and the ground select transistor 256 are connected in series with the cell chain. For example, the bit line select transistor 254 is disposed adjacent the first memory cell 252₁ and the ground select transistor 256 may be disposed adjacent the last memory cell 252ₙ. In some embodiments, the bit line select transistor 254 and the ground select transistor 256 may be formed from the same fin(s) with the memory cells 252₁, . . . 252ₙ.

The memory circuit 250 includes an array of multi-MTP cell 252 arranged in an array. FIGS. 6A and 6B show two rows of the multi-MTP cells 252 with one column in each row. It should be noted that the memory circuit 250 may include multiple rows of multi-MTP cells 252 with each row includes two or more multi-MTP cells 252. The memory circuit 250 further includes a plurality of bit lines BLk (k is an integer), a plurality of source lines SLm (m is an integer), a plurality of word lines WLn (n is an integer). The plurality of word lines WLn may be connected to a word line decoder. The plurality of bit lines BLk may be connected to a bit line decoder 206.

Each bit line BLk is operably coupled to the bit line select transistor(s) 254 of the multi-MTP cell(s) 252 in the k^{th} row. Each word line WLn is operable coupled to the control gate or second gate electrode of the memory cell 252n in the multi-MTP cell 252 in the plurality of rows of the multi-MTP cell(s) 252. Each source line SLm is connected to the ground select transistor 256 of the m^{th} the multi-MTP cell(s) 252 in a row. The memory cells 252₁, . . . 252ₙ in each multi-MTP cell 252 share one source line SLm. As discussed above, each of the memory cells 252₁, . . . 252ₙ, may have the structure of the memory cell 100 or 100a discussed above. In the memory circuit 250, the control gate or the second gate electrode layer 116 of the memory cell 100 (memory cell 252) is connected to the corresponding word line WLn. However, the source region 108s and the drain region 108d of each memory cell 100 are not in direct contact with the source line SLm or the bit line BLk. Instead, the source region 108s and the drain region 108d of each memory cell 100 are connected with the corresponding source line SLm or the bit line BLk via the ground select transistor 256 and the bit line select transistor 254 in the multi-MTP cell 252. This configuration allows minimization of the memory cell 100, 100a, thus, thereby achieving high cell density.

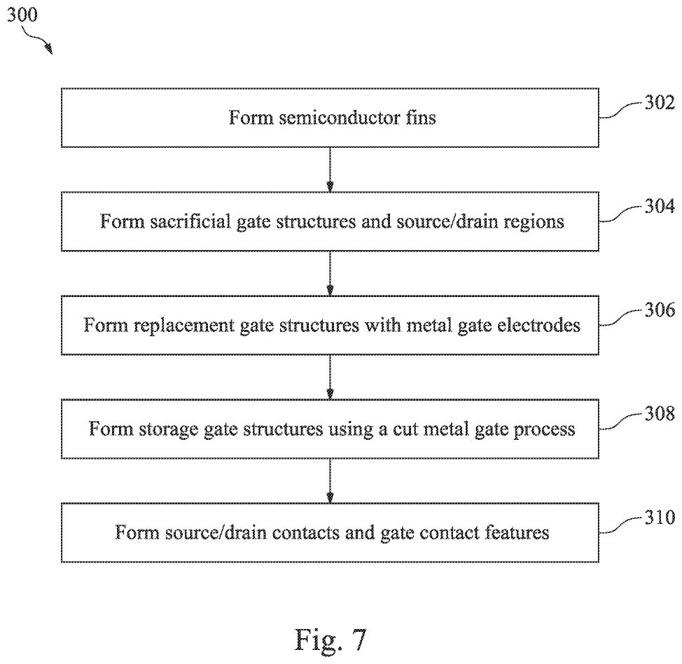

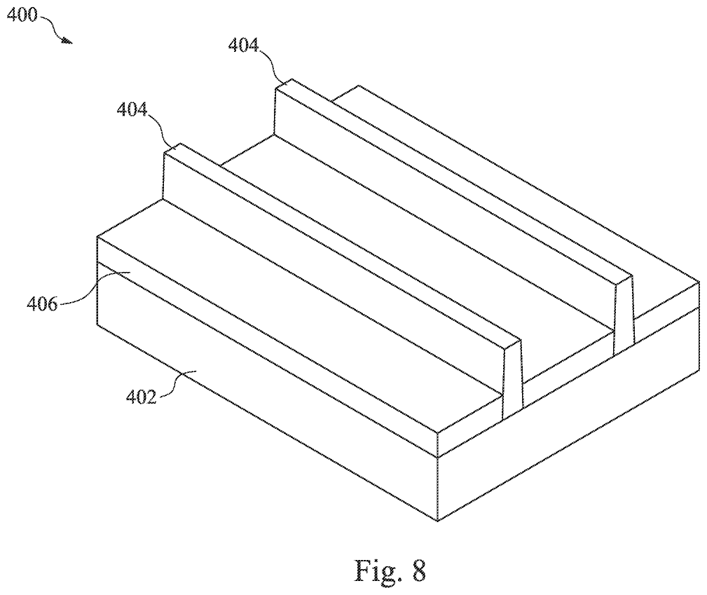

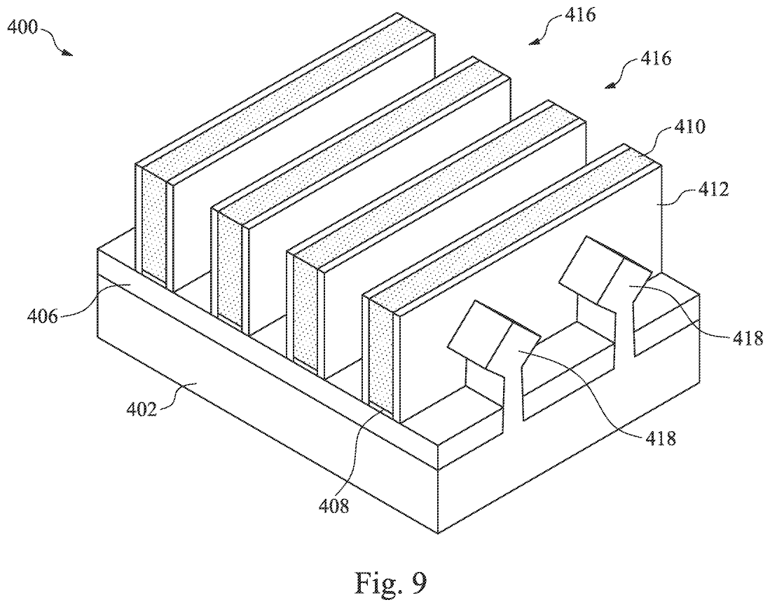

FIG. 7 is a flow chart of a method 300 for forming a memory circuit according to embodiments of the present disclosure. FIGS. 8-10, 10A-10C, 11, 11A-11C, 12, 12A-12C, and 13A-13C illustrate various views of the forming a memory circuit 400 according to embodiment of the present disclosure. The memory circuit 400 may include a plurality of memory cells, similar to the memory cell 100 discussed above.

At operation 302 of the method 300, semiconductor fins 404 are formed on a substate 402, and an isolation layer 406 is formed in trenches between the semiconductor fins 404, as shown in 8. FIG. 8 is a schematic perspective view of the memory circuit 400 according to the present disclosure. The substrate 402 may include a single crystalline semiconductor material such as, but not limited to Si, Ge, SiGe, GaAs, InSb, GaP, GaSb, InAlAs, InGaAs, GaSbP, GaAsSb, and InP. The substrate 402 may include various doping configurations depending on circuit design. For example, the substrate 402 may one or more p-doped regions and one or more n-doped regions. The semiconductor fins 404 are then formed using one or more patterning and etching processes. The isolation layer 406 is formed in the trenches between the semiconductor fins 404 by a suitable deposition followed by an etch back process. The bottom profile of the isolation layer 406 is shown to be curved as an example. Depending on pitch and/or height of the semiconductor fins 404, a bottom profile of the isolation layer 406 may vary, for example curved, substantially flat, or other shapes. The isolation layer 406 may be formed by a high-density plasma chemical vapor deposition (HDP-CVD), a flowable CVD (FCVD), or other suitable deposition process. In some embodiments, the isolation layer 406 may include silicon oxide, silicon nitride, silicon oxynitride, fluorine-doped silicate glass (FSG), a low-k dielectric, combinations thereof. In some embodiments, the isolation layer 406 is formed to cover the semiconductor fins 404 by a suitable deposition process to fill the trenches between the semiconductor fins 404, a planarization process may be performed to expose the semiconductor fins 404, and then recess etched using a suitable anisotropic etching process to expose a portion of the semiconductor fins 404, as shown in FIG. 8.

At operation 304, sacrificial gate structures 416 and source/drain regions 418 are formed, as shown in FIG. 9. FIG. 9 is a schematic perspective view of the memory circuit 400 according to the present disclosure.

To form the sacrificial gate structures 416, a sacrificial gate dielectric layer 408 is conformally formed over the substrate 402. The sacrificial gate dielectric layer 408 is formed over the semiconductor fins 404 and the isolation layer 406. The sacrificial gate dielectric layer 408 may include silicon oxide, silicon nitride, a combination thereof, or the like. The sacrificial gate dielectric layer 408 may be deposited or thermally grown according to acceptable techniques, such as thermal CVD, CVD, ALD, and other suitable methods.

A sacrificial gate electrode layer 410 is deposited on the sacrificial gate dielectric layer 408 and then planarized, such as by a CMP process. The sacrificial gate electrode layer 410 includes silicon such as polycrystalline silicon, amorphous silicon, poly-crystalline silicon-germanium (poly-SiGe), or the like. In some embodiments, the sacrificial gate electrode layer 410 is subjected to a planarization operation. The sacrificial gate electrode layer 410 may be deposited using CVD, including LPCVD and PECVD, PVD, ALD, or other suitable process. A patterning operation is performed on the sacrificial gate electrode layer 410, and the sacrificial gate dielectric layer 408 to form the sacrificial gate structures 416 using one or more etching processes, such as one or more plasma etching processes or one or more wet etching processes. In some embodiments, a mask layer and a pad layer (not shown) are first patterned using a patterning process. The sacrificial gate electrode layer 410 is then patterned using the patterned mask layer and pad layer as an etching mask. In some embodiments, the sacrificial gate electrode layer 410 may be etched by an anisotropic etching, such as a reactive ion etching (RIE) process. The anisotropic etching has a greater etching rate along the Z direction than etching rates along the X and Y directions. During the etching of the sacrificial gate electrode layer 410, the sacrificial gate dielectric layer 408 on the semiconductor fins 404 may act as an etch stop to prevent the etchant from removing the semiconductor fins 404. In some embodiments, after patterning the sacrificial gate electrode layer 410, any exposed residual sacrificial gate dielectric layer 408 is removed by a suitable etch process. In some embodiments, the residual sacrificial gate dielectric layer 408 can be etched by tuning one or more parameters, such as etchant, etching temperature, etching solution concentration, etching pressure, source power, radio frequency (RF) bias voltage, etchant flow rate, of the etch process for etching the sacrificial gate electrode layer 410.

The sacrificial gate structures 416 cover a portion of the semiconductor fins 404. The portion of the semiconductor fins 404 covered by the sacrificial gate structures 416 eventually form a channel region. Gate sidewall spacers 412 are formed on sidewall of the sacrificial gate structures 416. The gate sidewall spacers 412 may have include one or more dielectric layers.

The semiconductor fins 404 not covered by the sacrificial gate structures 416 are recess etched to form source/drain recesses on both sides of the sacrificial gate structures 416. Epitaxial source/drain regions 418 are formed in the source/drain recess. In some embodiments, the epitaxial source/drain regions 418 may be grown in an epitaxial chamber by a suitable process.

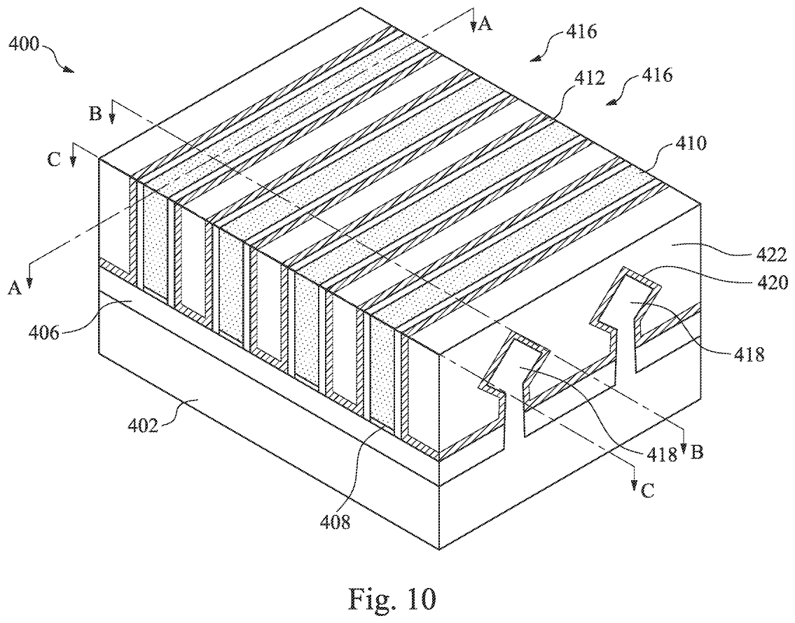

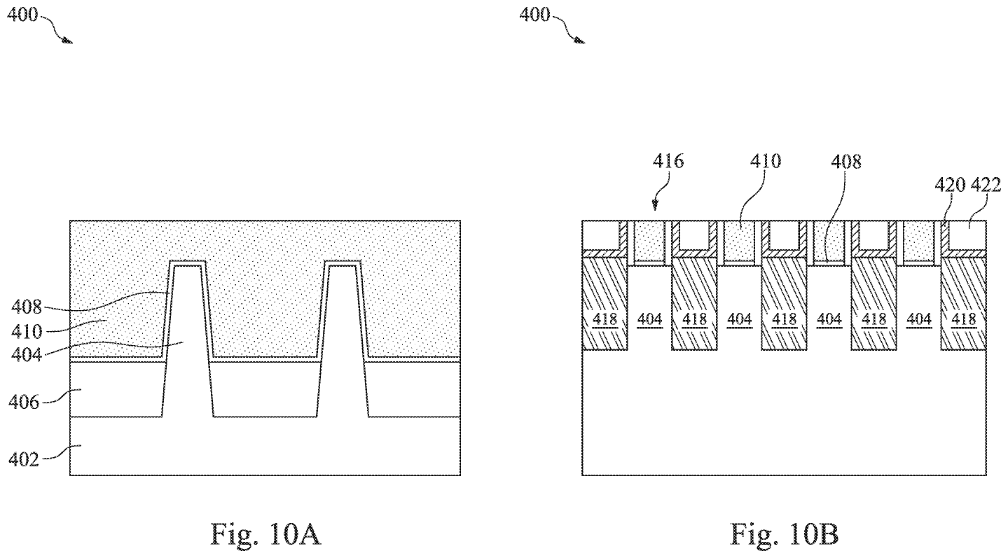

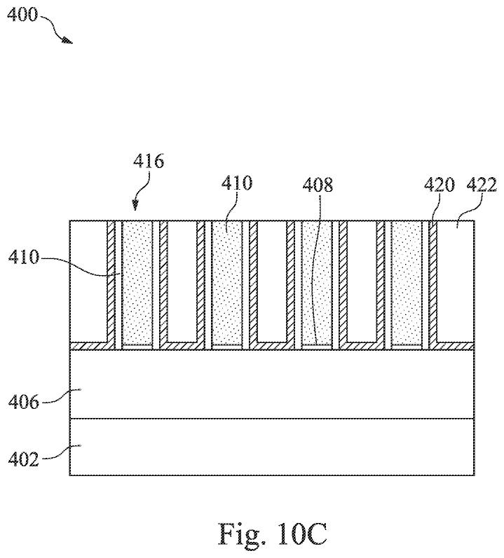

A contact etch stop layer (CESL) 420 and an interlayer dielectric (ILD) layer 422 are formed over the memory circuit 400, as shown in FIGS. 10, 10A, 10B, and 10C. FIG. 10 is a schematic perspective view of the memory circuit 400 according to the present disclosure. FIGS. 10A, 10B, and 10C are schematic sectional view of the memory circuit 400 along lines A-A, B-B, and C-C in FIG. 10 respectively.

The CESL 420 is conformally formed over exposed surfaces of the memory circuit 400. The CESL 420 is formed on the epitaxial source/drain regions 418, the gate sidewall spacers 412, and the isolation layer 406 if exposed. The CESL 420 may include SiN, SiON, SiCN or any other suitable material, and may be formed by CVD, PVD, or ALD. The interlayer dielectric (ILD) layer 422 is formed over the CESL 420. The materials for the ILD layer 422 include compounds comprising Si, O, C, and/or H, such as silicon oxide, SiCOH and SiOC. Organic materials, such as polymers, may be used for the ILD layer 422. In some embodiments, the ILD layer 422 may be formed by flowable CVD (FCV). The ILD layer 422 protects the epitaxial source/drain regions 418 during the removal of the sacrificial gate structures 416.

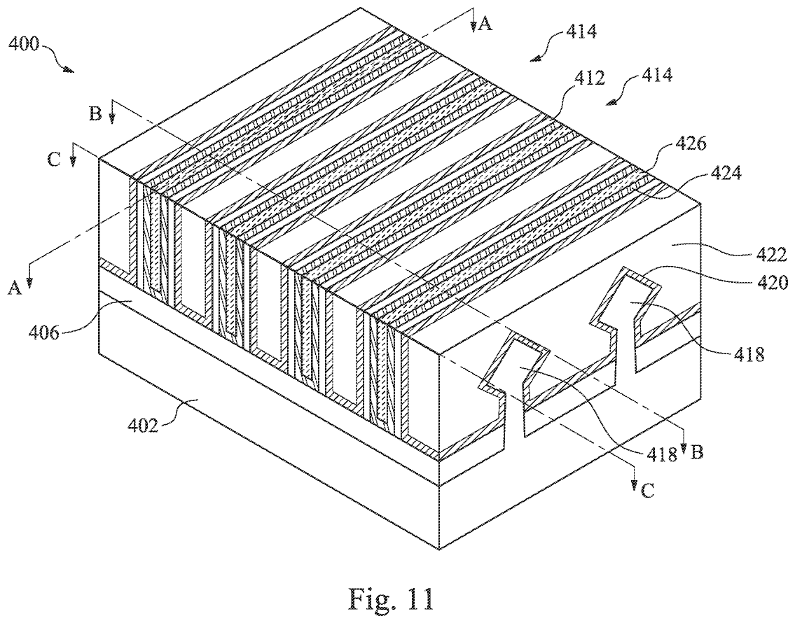

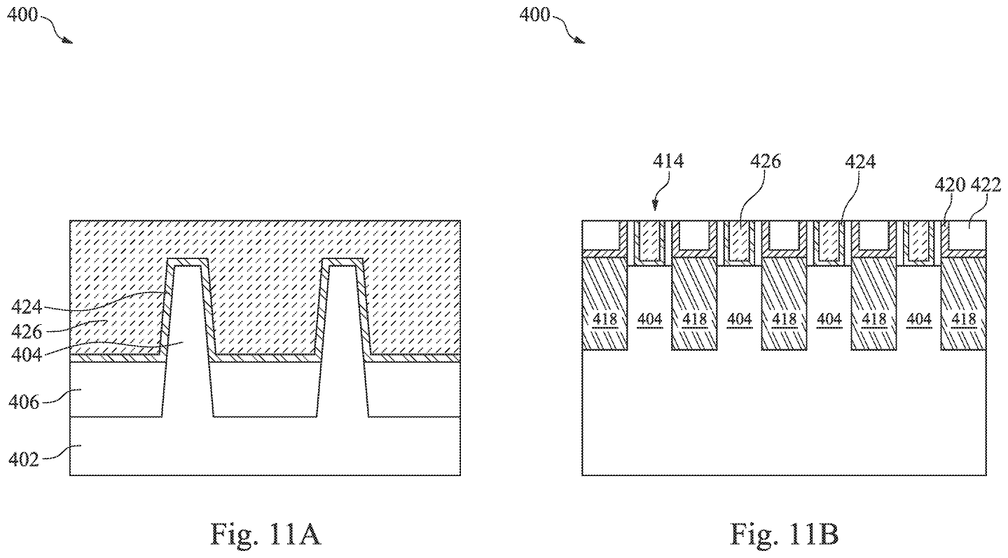

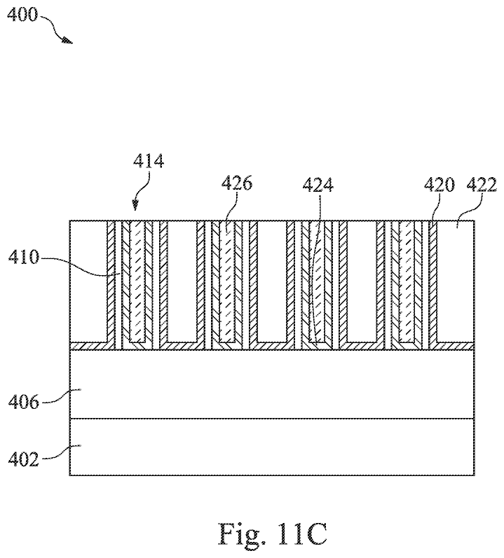

At operation 306, replacement gate structures 414 are formed as shown in FIGS. 11, 11A, 11B, and 11C. FIG. 11 is a schematic perspective view of the memory circuit 400 according to the present disclosure. FIGS. 11A, 11B, and 11C are schematic sectional view of the memory circuit 400 along lines A-A, B-B, and C-C in FIG. 11 respectively.

The sacrificial gate dielectric layer 408 and sacrificial gate electrode layer 410 are removed by one or more suitable process, such as dry etch, wet etch, or a combination thereof, to expose the semiconductor fins 404. In some embodiments, a wet etchant such as a tetramethylammonium hydroxide (TMAH) solution is used. The replacement gate structure may include a first gate dielectric layer 424, and a gate electrode layer 426.

The first gate dielectric layer 424 may be conformally deposited on exposed surfaces in the gate cavities. The first gate dielectric layer 424 may have different composition and dimensions for N-type devices and P-type devices and are formed separately using patterned mask layers and different deposition recipes. The first gate dielectric layer 424 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The first gate dielectric layer 424 may be formed by CVD, ALD or any suitable method.

The gate electrode layer 426 is then formed on the first gate dielectric layer 424 to fill the gate cavities. The gate electrode layer 426 may include one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 426 may be formed by CVD, ALD, electro-plating, or other suitable method. After the formation of the gate electrode layer 426, a planarization process, such as a CMP process, is performed to remove excess deposition of the gate electrode material and expose the top surface of the ILD layer 422.

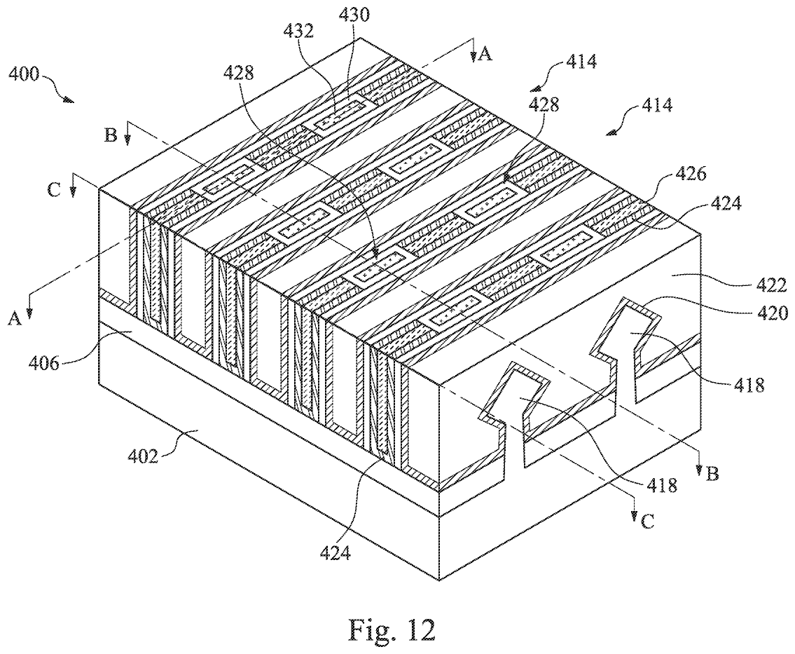

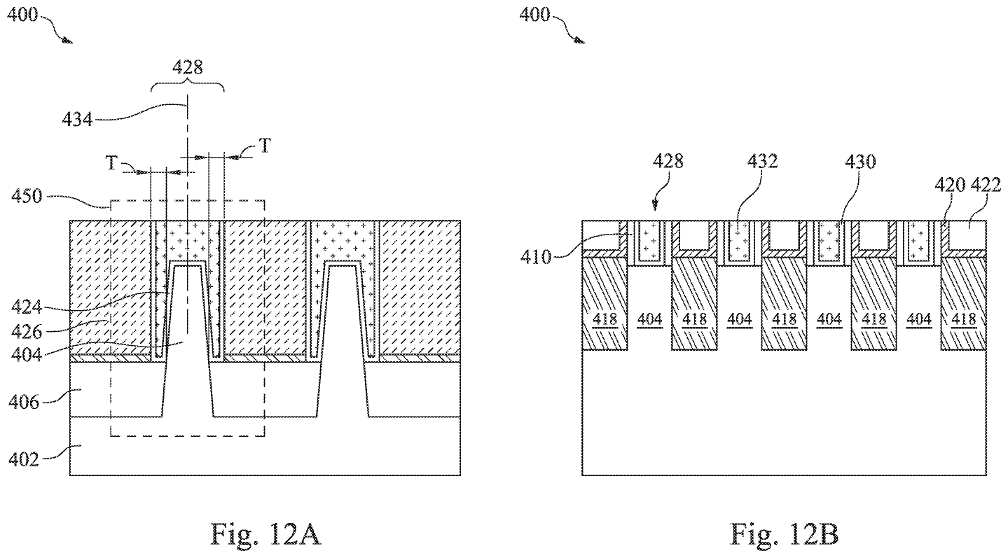

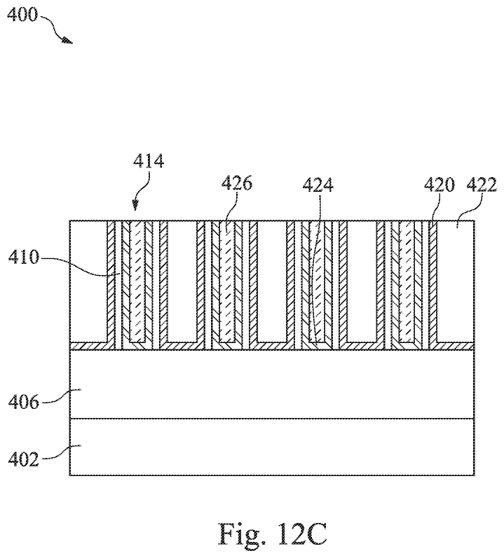

At operation 308, storage nodes 428 are formed over the semiconductor fins 404 between the sidewall spacers 412, as shown in FIGS. 12, 12A, 12B, 12C. FIG. 12 is a schematic perspective view of the memory circuit 400 according to the present disclosure. FIGS. 12A, 12B, and 12C are schematic sectional view of the memory circuit 400 along lines A-A, B-B, and C-C in FIG. 12 respectively.

The storage nodes 428 are formed within the replacement gate structures 414 and over the semiconductor fins 404. A patterning process may be performed to “cut” the replacement gate structures 414 into sections by removing the gate electrode layer 426 and the first gate dielectric layer 424 over the semiconductor fins 404. After the cutting process, the semiconductor fins 404 are exposed between the sidewall spacers 412. A second gate dielectric layer 430 is then deposited over the exposed surfaces including the semiconductor fins 404, the isolation layer 406, the sidewall spacers 412, the first gate dielectric layer 424, and the gate electrode layer 426. A storage gate electrode layer 432 is then deposited over the second gate dielectric layer 430 and fills the openings over the semiconductor fins 404. The storage gate electrode layer 432 and the second gate dielectric layer 430 form the storage nodes 428.

In some embodiments, the second gate dielectric layer 430 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the second gate dielectric layer 430 may include SiOx, HfOx, and ZrOx, or a combination thereof. The second gate dielectric layer 430 may be selected may be formed by CVD, ALD or any suitable method. The composition and dimension of the second gate dielectric layer 430 may be selected according to circuit design.

In some embodiments, the storage gate electrode layer 432 may include one or more layers of material suitable for trapping electrons therein. In some embodiments, the storage gate electrode layer 432 be formed from silicon nitride, silicon oxynitride, alloy of silicon oxide and silicon nitride, a combination thereof, or any suitable material for storing charges therein. The storage gate electrode layer 432 may be formed by CVD, ALD or any suitable method. After deposition of the storage gate electrode layer 432, a planarization process, such as CMP, may be performed to expose the gate electrode layer 426 for subsequent formation of gate contact features.

In some embodiments, the storage nodes 428 may be formed substantially symmetrical about a central axis 434 of the corresponding semiconductor fin 404. As shown in FIG. 12A, the storage gate electrode layer 432 may have substantially equal thickness T on either side of the semiconductor fin 404. The thickness T may be in a range between about 5 nm and about 100 nm. In some embodiments, the second gate dielectric layer 430 may have a thickness in a range between about 2 nm and about 10 nm. In some embodiments, a ratio of the thickness of the second gate dielectric layer 430 over the storage gate electrode layer 432 may be in a range between about 0.01 and about 0.2.

As shown in FIG. 12A, the second gate dielectric layer 430 is disposed between the gate electrode layer 426 and the storage gate electrode layer 432. In some embodiments, the first gate dielectric layer 424 and the second gate dielectric layer 430 may be formed from the same material. In other embodiments, the first gate dielectric layer 424 and the second gate dielectric layer 430 may be formed different material according to circuit design.

After operation 308, a plurality of memory cells 450 are formed over the substrate 402. The memory cells 450 are similar to the memory cell 100 of FIGS. 1A-1C.

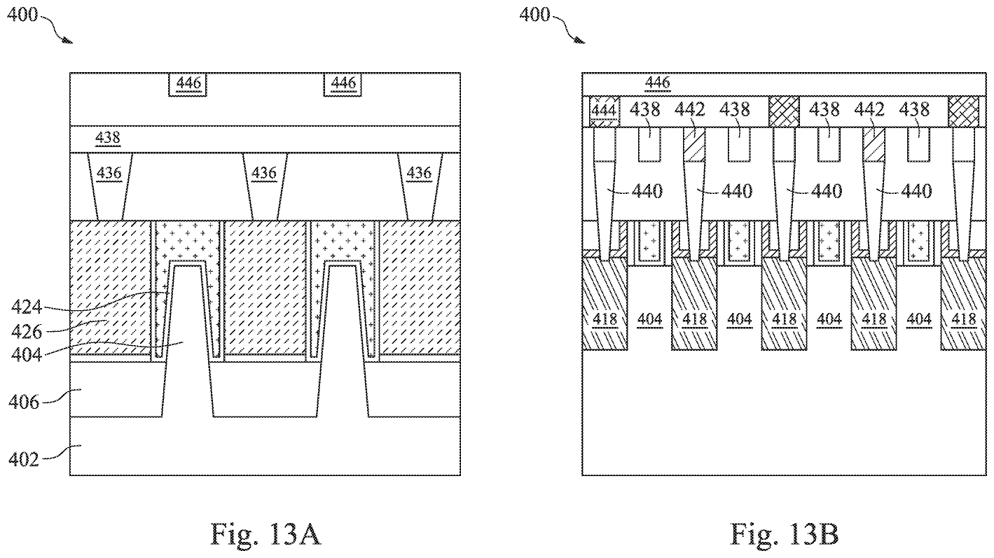

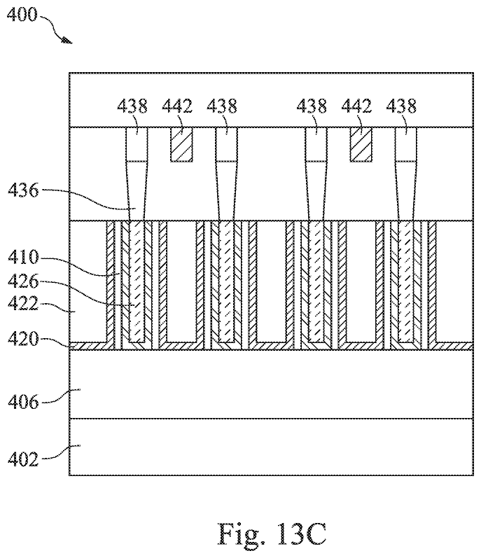

At operation 310, gate contact features 436 and/or source/drain contact features 440 may be formed to connect the memory cells 450, as shown in FIGS. 13A, 13B, 13C. FIGS. 13A, 13B, and 13C are schematic sectional view of the memory circuit 400 along lines A-A, B-B, and C-C in FIG. 12 respectively.

In operation 310, conductive lines and vias are formed in dielectric materials in layers to provide electrical connection to the source/drain regions 418 and the gate electrode layer 426 so that the memory cells 450 may be read, programmed, and erased. In some embodiments, the gate contact features 436 are formed to connect the gate electrode layer 426 to word lines 438. The source/drain contact features 440 are formed to connect the source/drain regions 418 to source lines 442 or to bit lines 446 via conductive vias 444. In some embodiments, the word lines 438 and the source lines 442 are disposed in a first IMD layer and extend along the y-axis, while the bit lines 446 are disposed in a second IMD layer and extend along the x-axis. The conductive lines and vias may be arranged in different configurations according to circuit design.

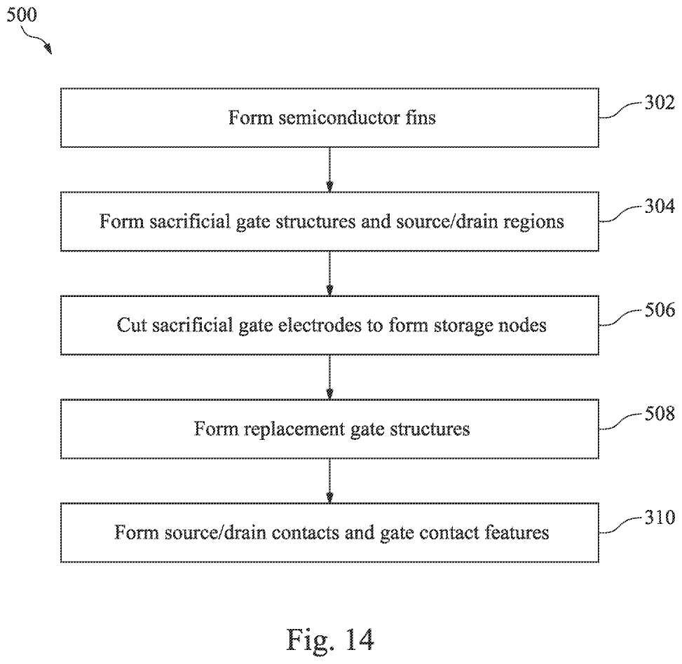

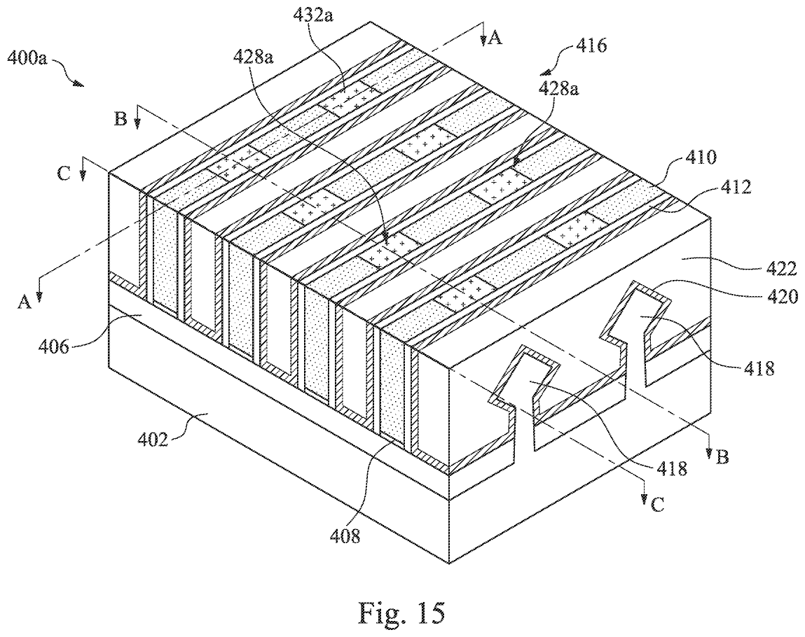

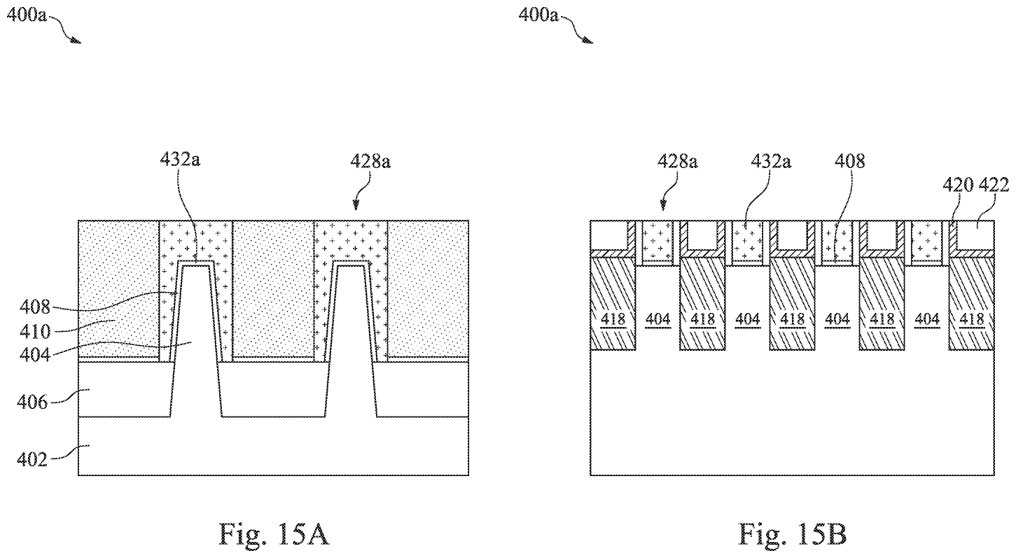

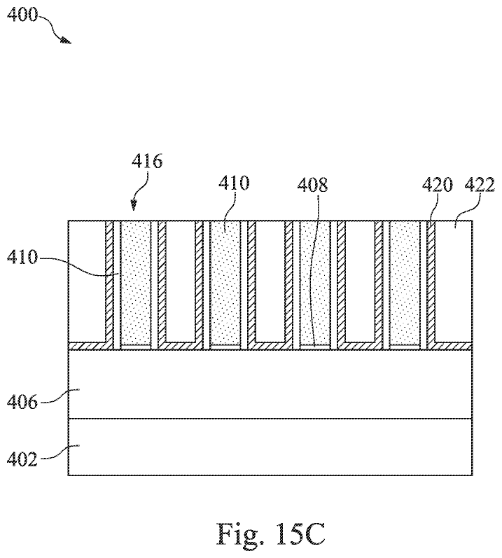

FIG. 14 is a flow chart of a method 500 for forming a memory circuit according to embodiments of the present disclosure. FIGS. 15, 15A-15C, 16, 16A-16C, and 17A-17C illustrates various views of the forming a memory circuit 400a according to embodiment of the present disclosure. The memory circuit 400a may include a plurality of memory cells, similar to the memory cell 100 discussed above. The method 500 starts with operation 302 and 304 as discussed above and shown in FIGS. 8-10.

In operation 506, storage nodes 428a by cutting sacrificial gate electrode 410 over the semiconductor fins 404 and depositing a storage gate electrode layer 432a, as shown in FIGS. 15, 15A, 15B, 15C. FIG. 15 is a schematic perspective view of the memory circuit 400a according to the present disclosure. FIGS. 15A, 15B, and 15C are schematic sectional view of the memory circuit 400a along lines A-A, B-B, and C-C in FIG. 15 respectively.

The storage nodes 428a are formed within the sacrificial gate structures 416 and over the semiconductor fins 404. A patterning process may be performed to “cut” the sacrificial gate electrode layer 410 into sections by patterning and etching process. After the cutting process, the sacrificial gate dielectric layer 408 is exposed between the sidewall spacers 412. The storage gate electrode layer 432a is then deposited over the sacrificial gate dielectric layer 408 and fills the openings between the sidewall spacers 412. The storage gate electrode layer 432a and the sacrificial gate dielectric layer 408 form the storage nodes 428a. The storage gate electrode layer 432a is in contact with the sidewall spacers 412 and the sections of the sacrificial gate electrode layer 410.

In some embodiments, the storage gate electrode layer 432a may include one or more layers of material suitable for trapping electrons therein. In some embodiments, the storage gate electrode layer 432a be formed from silicon nitride, silicon oxynitride, alloy of silicon oxide and silicon nitride, a combination thereof, or any suitable material for storing charges therein. The storage gate electrode layer 432a may be formed by CVD, ALD or any suitable method. After deposition of the storage gate electrode layer 432a, a planarization process, such as CMP, may be performed to expose the sacrificial gate electrode layer 410 for replacement gate process.

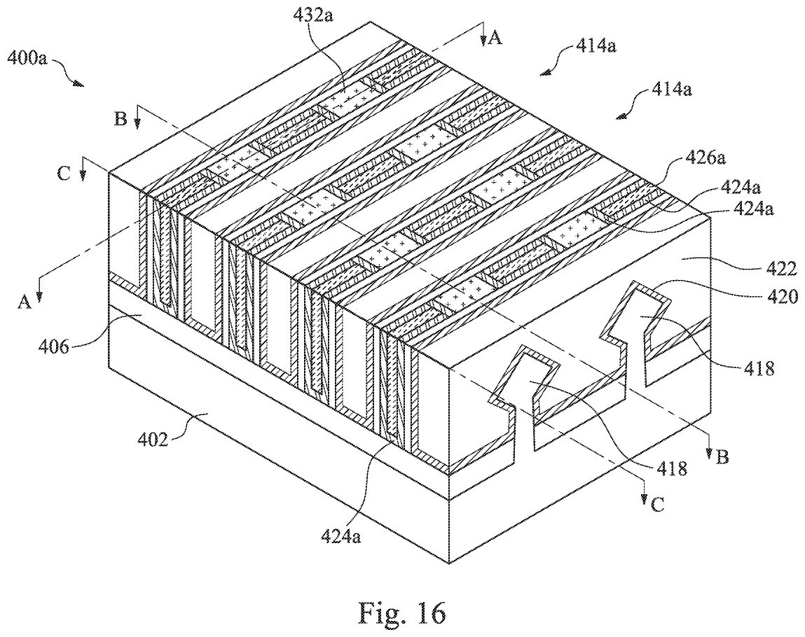

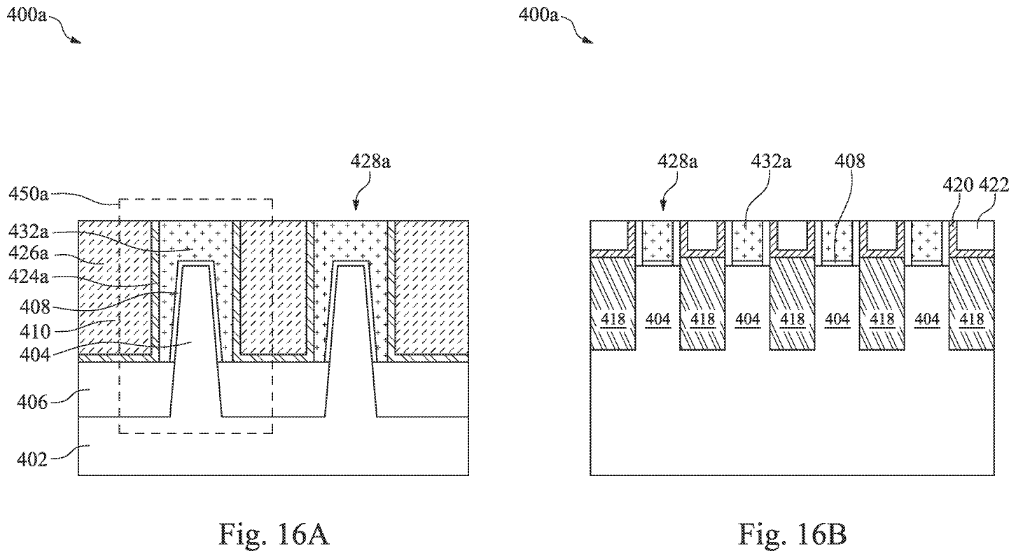

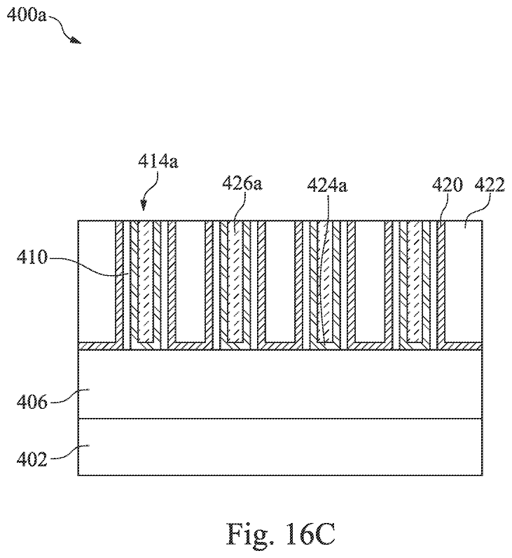

At operation 508, replacement gate structures 414a are formed as shown in FIGS. 16, 16A, 16B, and 16C. FIG. 16 is a schematic perspective view of the memory circuit 400a according to the present disclosure. FIGS. 16A, 16B, and 16C are schematic sectional view of the memory circuit 400a along lines A-A, B-B, and C-C in FIG. 16 respectively.

In some embodiments, the sacrificial gate electrode layer 410 is selectively etched to expose the sacrificial gate dielectric layer 408 below. In some embodiments, the sacrificial gate dielectric layer 408 may be removed by one or more suitable process, such as dry etch, wet etch, or a combination thereof, to expose the semiconductor fins 404. Gate cavities are formed between the sidewall spacers 412 and between the storage gate electrode layer 432a.

A gate dielectric layer 424a is then deposited on exposed surfaces in the gate cavities. Particularly, the gate dielectric layer 424a may be deposited over sidewalls of the storage gate electrode layer 432a, the sidewall spacers 412, and the isolation layer 406.

The first gate dielectric layer 424a may have different composition and dimensions for N-type devices and P-type devices and are formed separately using patterned mask layers and different deposition recipes. The gate dielectric layer 424a may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 424a may be formed by CVD, ALD or any suitable method.

The gate electrode layer 426a is then formed on the gate dielectric layer 424a to fill the gate cavities. The gate electrode layer 426a may include one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 426a may be formed by CVD, ALD, electro-plating, or other suitable method. After the formation of the gate electrode layer 426a, a planarization process, such as a CMP process, is performed to remove excess deposition of the gate electrode material and expose the top surface of the ILD layer 422.

After operation 508, a plurality of memory cells 450a are formed over the substrate 402. The memory cells 450a are similar to the memory cell 100 of FIGS. 1A-1C.

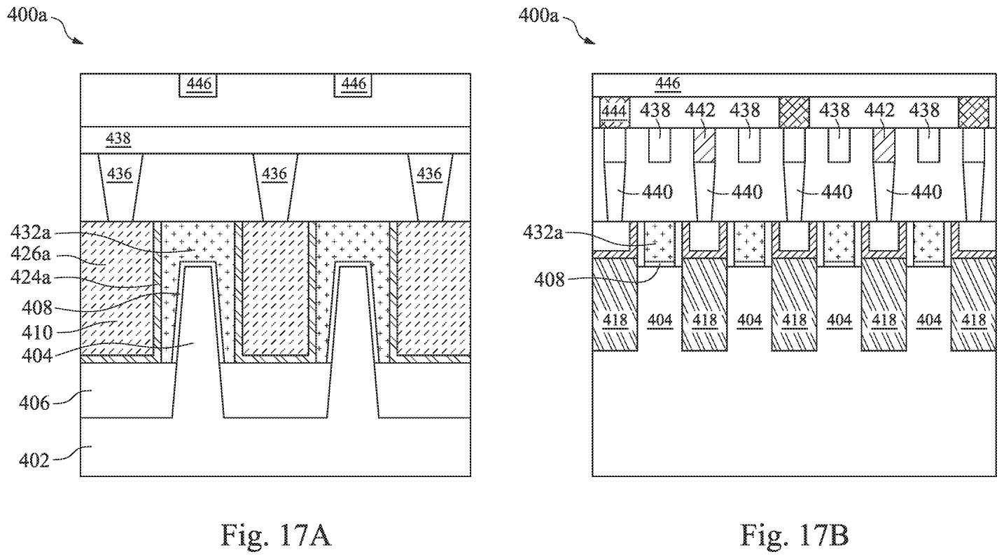

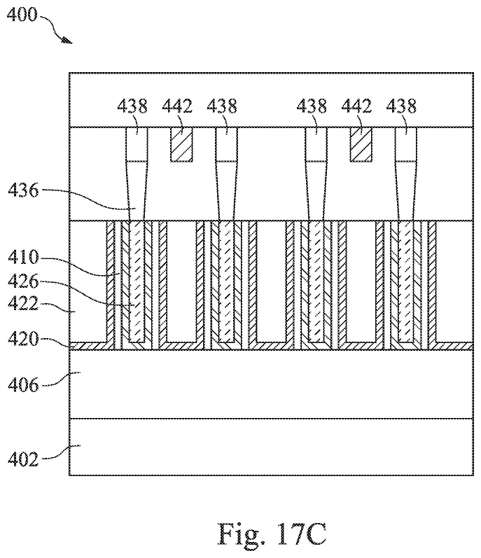

Operation 310 is then performed to form gate contact features 436 and/or source/drain contact features 440 may be formed to connect the memory cells 450a, as shown in FIGS. 17A, 17B, 17C. FIGS. 17A, 17B, and 17C are schematic sectional view of the memory circuit 400 along lines A-A, B-B, and C-C in FIG. 16 respectively.

Embodiments the present disclosure provide a MTP memory cell and methods for forming the same. The MTP memory cell includes a FinFET transistor having a storage node formed around the channel region and a metal gate electrode around the storage node. The memory cell may be implemented by either n-channel transistor or p-channel transistor, thus, providing design flexibility. The MTP memory cell only includes a single transistor, thus, may be used to achieve high density memory array. The MTP memory cell may be programmed/erased by various methods, including CHE, BBHH, and FN tuning, thus, provide additional design choices. Furthermore, the MTP memory cell may be fabricated using existing processing sequences, such as cut metal gate sequence.

It will be understood that not all advantages have been necessarily discussed herein, no particular advantage is required for all embodiments or examples, and other embodiments or examples may offer different advantages.

Embodiments of the present disclosure provide a memory cell, comprising a source region; a drain region; a channel region connecting the source region and the drain region; a first gate dielectric layer disposed on the channel region; a storage gate electrode layer disposed on the first gate dielectric layer; and a second gate electrode layer disposed on the storage gate electrode layer, wherein the second gate electrode layer comprises a conductive material; and a second gate dielectric layer disposed between the storage gate electrode layer and the second gate electrode layer.

Some embodiments of the present disclosure relate to a method for operating a memory cell, comprising providing a multi-time programmable memory cell comprising: a source region; a drain region; a channel region connected between the source region and the drain region; a storage node formed on the channel region; and a control gate on the storage node; injecting electrons to the storage node by applying a first control voltage on the control gate; and removing electrons from the storage node by applying a second control voltage on the control gate.

Some embodiments of the present disclosure relate to an integrated circuit, comprising an array of memory cells, wherein each memory cell comprising a source region; a drain region; a channel region connected between the source region and the drain region; a storage node formed on the channel region; and a control gate on the storage node; a plurality of word lines, wherein each word line is connected to the control gates in one column of memory cells in the array; a bit line in connection with the drain regions of a row of memory cells in the array; and a source line in connection with the source region of at least one column of memory cells in the array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory cell, comprising:
a source region;
a drain region;
a channel region connecting the source region and the drain region;
a first gate dielectric layer disposed on the channel region;
a storage gate electrode layer disposed on the first gate dielectric layer; and
a second gate electrode layer disposed on the storage gate electrode layer, wherein the second gate electrode layer comprises a conductive material; and
a second gate dielectric layer disposed between the storage gate electrode layer and the second gate electrode layer.

2. The memory cell of claim 1, wherein the storage gate electrode layer comprises silicon nitride.

3. The memory cell of claim 2, wherein the channel region comprises a semiconductor fin having a first sidewall and a second sidewall, the storage gate electrode layer is disposed over the first sidewall and the second sidewall.

4. The memory cell of claim 3, wherein the second gate electrode layer has a first portion and a second portion, the first portion of the second gate electrode layer is facing the first sidewall of the channel region, and the second portion of the second gate electrode layer is facing the second sidewall of the channel region.

5. The memory cell of claim 4, further comprising a first gate contact feature in contact with the first portion of the second gate electrode layer, a second gate contact feature in contact with the second portion of the second gate electrode layer, and the first gate contact feature and the second gate contact feature are electrically coupled.

6. The memory cell of claim 1, wherein the channel region is a p-type channel.

7. The memory cell of claim 1, wherein the channel region is a n-type channel.

8. The memory cell of claim 3, wherein the channel region comprises two or more semiconductor fins.

9. A method for operating a memory cell, comprising:
providing a multi-time programmable memory cell comprising:
a source region;
a drain region;
a channel region connected between the source region and the drain region;
a storage node formed on the channel region; and
a control gate on the storage node;
injecting electrons to the storage node by applying a first control voltage on the control gate; and
removing electrons from the storage node by applying a second control voltage on the control gate.

10. The method of claim 9, wherein injecting electrons to the storage node comprising:
applying a source voltage on the source region; and
applying a drain voltage on the drain region, wherein the first control voltage is a positive voltage, and the source voltage and drain voltage are about 0V.

11. The method of claim 9, wherein injecting electrons to the storage node comprising:
applying a source voltage on the source region; and
applying a drain voltage on the drain region, wherein the first control voltage is a positive voltage, the source voltage is about 0V, and the drain voltage is a positive voltage.

12. The method of claim 9, wherein removing electrons from the storage node comprising:
applying a source voltage on the source region; and
applying a drain voltage on the drain region, wherein the second control voltage is a negative voltage, and the source voltage and drain voltage are about 0V.

13. The method of claim 9, wherein removing electrons from the storage node comprising:
applying a source voltage on the source region; and
applying a drain voltage on the drain region, wherein the second control voltage is a positive voltage, the source voltage and drain voltage are positive voltages greater than the first voltage.

14. An integrated circuit, comprising:
an array of memory cells, wherein each memory cell comprising:
a source region;
a drain region;
a channel region connected between the source region and the drain region;
a storage node formed on the channel region; and
a control gate on the storage node;
a plurality of word lines, wherein each word line is connected to the control gates in one column of memory cells in the array;
a bit line in connection with the drain regions of a row of memory cells in the array; and
a source line in connection with the source region of at least one column of memory cells in the array.

15. The integrated circuit of claim 14, wherein the source line is in connection with source regions of two neighboring columns of memory cells in the array.

16. The integrated circuit of claim 15, wherein two neighboring memory cells in the same row share a contact feature to connect with the bit line.

17. The integrated circuit of claim 15, wherein the source line and the plurality of word lines extend along a first direction, and the bit line extends along a second direction.

18. The integrated circuit of claim 14, further comprising:
a bit line select transistor; and
a source select transistor, wherein the bit line select transistor and the source select transistor are connected to a row of memory cells in series, the bit line is connected to the row of memory cell via the bit line transistor, and the source line is connected to source regions via the source select transistor.

19. The integrated circuit of claim 18, wherein the source region and the drain region of the memory cell are not in contact with conductive features.

20. The integrated circuit of claim 14, wherein the control gate in each memory cell comprises two sections disposed on two sides of the storage node and connected to a corresponding word line.
